(19) United States
(12) Patent Application Publication
(10) Pub. No.: US 2025/0201611 A1
(43) Pub. Date: Jun. 19, 2025

(54) SUPPORT UNIT AND CONTAINER STORAGE SYSTEM COMPRISING THE SAME

(71) Applicant: SEMES CO., LTD., Chungcheongnam-do (KR)

(72) Inventor: Sung Ho LEE, Chungcheongnam-do (KR)

(21) Appl. No.: 18/979,586

(22) Filed: Dec. 12, 2024

(30) Foreign Application Priority Data
Dec. 13, 2023 (KR) 10-2023-0180489

(51) Int. Cl. H01L 21/677

(52) U.S. Cl. CPC H01L 21/67706; H01L 21/6773

(57) ABSTRACT

A support unit supporting a transport article in a container storage system provided in a semiconductor fabricating plant and storing the transport article, the transport article being provided as a first container and a second container having a different shape from the first container, includes: a base including a first surface forming an upper surface or a lower surface and a second surface forming an opposite surface to the first surface; a first fixing body protruding from the first surface and interfering with the first container to fix the first container; and a second fixing body protruding from the second surface and interfering with the second container to fix the second container, wherein the first surface of the base faces upward so that the first container is supported or the second surface of the base faces upward so that the second container is supported.

### CROSS-REFERENCE TO RELATED APPLICATION

This application claims priority from Korean Patent Application No. 10-2023-0180489 filed on Dec. 13, 2023 in the Korean Intellectual Property Office, and all the benefits accruing therefrom under 35 U.S.C. 119, the contents of which in its entirety are herein incorporated by reference.

### BACKGROUND

### 1. Technical Field

The present disclosure relates to a support unit and a container storage system comprising the same.

### 2. Description of the Related Art

Semiconductor element fabricating processes may be continuously performed within a semiconductor fabricating facility, and may be divided into a pre-process and a post-process. The semiconductor fabricating facility may be installed in a space defined as a FAB in order to fabricate a semiconductor element.

The pre-process refers to a process of forming circuit patterns on a substrate (e.g., a wafer) to complete chips. Such a pre-process may include a deposition process of forming a thin film on the substrate, a photolithography process of transferring a photoresist onto the thin film using a photomask, an etching process of selectively removing unnecessary portions using a chemical material or a reactive gas in order to form desired circuit patterns on the substrate, an ashing process of removing the photoresist remaining after the etching process, an ion implantation process of implanting ions into portions connected to the circuit patterns to impart characteristics of an electronic element, a cleaning process of removing a contamination source on the substrate, and the like.

The post-process refers to a process of evaluating performance of a product completed through the pre-process. The post-process may include a substrate inspection process of inspecting whether or not each chip on the substrate operates to sort good and bad products, a package process of cutting and separating each chip through dicing, die bonding, wire bonding, molding, marking, etc., to form a shape of a product, a final inspection process of finally inspecting characteristics and reliability of the product through electrical characteristic inspection, burn-in inspection, etc., and the like.

An article such as the substrate may be transported by a transport carriage (e.g., an overhead hoist transport (OHT)) in a state in which it is received in a container. The transport carriage may move between substrate processing devices or move to another FAB to transport an article.

Meanwhile, in a case of containers transported by the transport carriage, shapes and/or types of containers used in the pre-process and the post-process are different from each other. For example, the container used in the pre-process may be provided as a front opening unified pod (FOUP), and the container used in the post-process may be provided as a cassette.

Since the shapes and the types of the containers used in the pre-process and the post-process are different from each other, different types of support units are provided in a container storage system such as a side track buffer (STB) so as to correspond to the shapes and the types of the containers, and the containers are transported to another factory as needed, and thus, only the FOUP or only the cassette is not stored in one container storage system, such that there is a case where the support unit supporting the FOUP and the cassette should be replaced according to each of the types of the containers. In addition, the support unit requires bolt assembling man hour so as to be individually separated/assembled, which causes operation loss, and thus, improvement is required.

### SUMMARY

Aspects of the present disclosure provide a support unit capable of being simply installed without needing to be replaced depending on a type of container by supporting two or more containers whose types are different from each other, and a container storage system comprising the same.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, a support unit supporting a transport article in a container storage system provided in a semiconductor fabricating plant and storing the transport article, the transport article being provided as a first container and a second container having a different shape from the first container, includes: a base including a first surface forming an upper surface or a lower surface and a second surface forming an opposite surface to the first surface; a first fixing body protruding from the first surface and interfering with the first container to fix the first container; and a second fixing body protruding from the second surface and interfering with the second container to fix the second container, wherein the first surface of the base faces upward so that the first container is supported or the second surface of the base faces upward so that the second container is supported.

According to another aspect of the present disclosure, a container storage system includes: a frame including one or more horizontal bars and one or more vertical bars connected to the horizontal bars; and the support unit as described above.

According to still another aspect of the present disclosure, a container storage system provided in a semiconductor fabricating plant and storing a transport article provided as a cassette and a front opening unified pod (FOUP) having one or more fitting holes formed at a lower end thereof, includes: a frame including one or more horizontal bars and one or more vertical bars connected to the horizontal bars; a support unit disposed on the horizontal bar and supporting the transport article; and a guide block positioned at a corner of the support unit in the frame and surrounding the support unit, wherein the support unit includes: a base including a first surface forming an upper surface or a lower surface and a second surface forming an opposite surface to the first surface; one or more first fixing bodies protruding from the first surface, having first inclined surfaces formed to be inclined downward toward the cassette, provided along corners of the cassette so that edges of a lower end of the cassette are in contact with the first fixing bodies, and having an L shape when viewed from above so as to correspond to two or more edges of the cassette; a guide pin protruding from the second surface and inserted into the fitting hole so as to interfere with the FOUP to fix the FOUP; a first rib protruding from the second surface, positioned to correspond to one side of the FOUP to face or be in contact with a lower peripheral surface or an edge of one side of the FOUP, and having a second inclined surface formed to be inclined upward in an outward direction; a second rib protruding from the second surface and positioned to correspond to the other side of the FOUP to face or be in contact with a lower peripheral surface or an edge of the other side of the FOUP; a reinforcing rib protrudes from at least one of the first surface and the second surface, protruding in parallel with an edge of the base between an outer side of the cassette and the FOUP and a corner of the base, and having a lower height than each of the first rib and the second rib; and a connection module provided as an electromagnet so as to attach the base to the horizontal bar by magnetic force and fixing the base to the horizontal bar, the guide block has a third inclined surface formed to be inclined downward toward the base, the base includes a first region where the first fixing body, the guide pin, the first rib, the second rib, and the reinforcing rib are provided and a second region provided outside the first region and in contact with the horizontal bar, and the first surface of the base faces upward so that the cassette is supported or the second surface of the base faces upward so that the FOUP is supported.

Detailed contents of other embodiments are described in a detailed description and are illustrated in the drawings.

With a support unit and a container storage system according to the present disclosure, two or more containers whose shapes or types are different from each other may be supported by one support unit, such that there is no need to prepare and replace the support unit depending on a type of container. Therefore, waste of a material due to the replacement of the support unit may be reduced, and the support unit may be simply installed, such that operation efficiency may be improved.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a view illustrating a transport system provided with a container storage system according to some exemplary embodiments of the present disclosure;

FIG. 2 is a perspective view illustrating the container storage system according to some exemplary embodiments of the present disclosure;

FIG. 3 is a plan view illustrating the container storage system according to some exemplary embodiments of the present disclosure;

FIG. 4 is a plan view illustrating a support unit according to some exemplary embodiments of the present disclosure;

FIG. 5 is a view illustrating a process in which the support unit according to some exemplary embodiments of the present disclosure is seated in the container storage system so that a first surface of the support unit faces upward;

FIG. 6 is a view illustrating a form in which a base of the support unit according to some exemplary embodiments of the present disclosure is guided by a guide block;

FIG. 7 is a view illustrating a state in which the support unit according to some exemplary embodiments of the present disclosure is seated in the container storage system so that the first surface of the support unit faces upward;

FIG. 8 is a view illustrating a process in which a first container is seated on the first surface of the support unit according to some exemplary embodiments of the present disclosure;

FIG. 9 is a view illustrating a state in which the first container is seated on the first surface of the support unit according to some exemplary embodiments of the present disclosure;

FIG. 10 is a view illustrating a process in which the support unit according to some exemplary embodiments of the present disclosure is turned over;

FIG. 11 is a view illustrating a state in which the support unit according to some exemplary embodiments of the present disclosure is seated in the container storage system so that a second surface of the support unit faces upward;

FIG. 12 is a perspective view illustrating a state in which a first surface of a support unit according to a first exemplary embodiment of the present disclosure faces upward; and

FIG. 13 is a perspective view illustrating a state in which a second surface of the support unit according to a first exemplary embodiment of the present disclosure faces upward.

### DETAILED DESCRIPTION OF THE EMBODIMENTS

Hereinafter, exemplary embodiments of the present disclosure will be described in detail with reference to the accompanying drawings. Advantages and features of the present disclosure and methods for accomplishing these advantages and features will become apparent from exemplary embodiments to be described later in detail with reference to the accompanying drawings. However, the present disclosure is not limited to exemplary embodiments to be disclosed below, and may be implemented in various different forms, these exemplary embodiments will be provided only in order to make the present disclosure complete and allow one of ordinary skill in the art to which the present disclosure pertains to completely recognize the scope of the present disclosure, and the present disclosure will be defined by the scope of the claims. Throughout the specification, the same components will be denoted by the same reference numerals.

The terms as used herein are for describing exemplary embodiments rather than limiting the present disclosure. In the present specification, a singular form includes a plural form unless stated otherwise in the phrase. The terms “comprise” and/or “comprising” as used herein do not exclude the existence or addition of one or more other components, steps, operations, and/or elements in addition to the mentioned components, steps, operations, and/or elements.

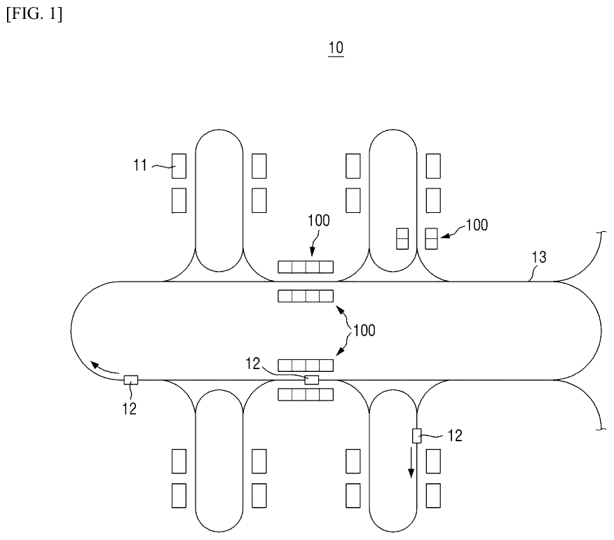

FIG. 1 is a view illustrating a transport system provided with a container storage system according to some exemplary embodiments of the present disclosure.

Referring to FIG. 1, a semiconductor or display fabricating plant 10 may be provided with substrate processing devices 11, vehicles 12, a rail unit 13, and container storage systems 100.

A plurality of substrate processing devices 11 may be provided, and may perform a plurality of fabricating processes such as a deposition process, a lithography process, and an etching process on a substrate (e.g., a wafer).

In addition, after a fabricating process is performed in any one substrate processing device 11, the substrate may be transported to another substrate processing device 11 for the next fabricating process. Here, the substrate may be transported in a state in which it is stored in a container 20 capable of accommodating a plurality of substrates. The container 20 may be transported by the vehicle 12. In order for the container 20 to be transported between the plurality of substrate processing devices 11, the rail unit 13 may form a movement path.

The vehicle 12 may move along the movement path formed by the rail unit 13. That is, a transport path for transporting an article between the substrate processing devices 11 may be formed. The transport path is the movement path of the vehicle 120, and may form an installation path of the rail unit 13. As an example, the rail unit 13 may be provided on the ceiling.

The rail unit 13 may have a structure in which straight lines and curved lines are combined with each other. The rail unit 13 may be provided with a plurality of bays where a transport operation is performed for the purpose of utilization of an operation space and easiness of management of the vehicle 12, and the plurality of bays are connected integrally with each other, such that the vehicle 12 does not move only in any one of the plurality of bays and may move to the plurality of bays neighboring to each other. The bay may have a loop structure. The bay having the loop structure is provided with a structure branching from/joining to the loop structure, such that the plurality of bays may be connected to each other.

The rail unit 13 may be provided with a power supply cable (not illustrated) supplying power to the vehicle 12 in a contactless manner (that may be a high-efficiency inductive power distribution (HID) or a contactless power supply (CPS)). The power supply cable may be installed in the entirety or a portion of the rail unit 13.

The vehicle 12 may transport the container 20 to the substrate processing device 11 while traveling along the movement path of the rail unit 13. The vehicle 12 moving along the rail unit 13 provided on the ceiling may be provided as an overhead hoist transport (OHT).

Although not illustrated in the drawings, the vehicle 12 may include a gripping unit gripping the container 20 and a driving module sliding or raising and lowering the gripping unit. The gripping unit of the vehicle 12 may load/unload the container 20 by sliding in a horizontal direction and then ascending or descending.

In addition, when the vehicle 12 transports the container 20 between the plurality of substrate processing devices 11, the container 20 may be transported directly from any one substrate processing device 11 to another substrate processing device 11 or may be stored in the container storage system 100 and then transported to another substrate processing device 11 or transported to another fabricating plant 10.

Here, the fabricating plant 10 may include a plurality of fabricating plants 10 that perform a pre-process and/or a post-process. The container 20 may be provided as a front opening unified pod (FOUP) storing a substrate to be processed in the pre-process, a cassette storing a wafer cut after substrate processing is completed in the post-process, or the like. Hereinafter, the container 20 is a transport article, and is described as including a first container 21 provided as the cassette and a second container 23 provided as the FOUP. Since the cassette and the FOUP have different shapes, it is difficult to store the cassette and the FOUP on the same support surface when the cassette and the FOUP are stored in the container storage system 100. For example, a second fixing body 230 fitted into a fitting hole 23H formed at a lower portion of the second container 23 provided as the FOUP may prevent separation of the second container 23 while guiding a position of the second container 23, but may have a protrusion structure to hinder the first container 21 provided as the cassette from being seated. That is, a bottom surface of the first container 21 is flat and the fitting hole 23H is not formed in the bottom surface of the first container 21, and thus, the second fixing body 230 may hinder the first container 21 from being put on a bottom surface.

Since it is difficult to store the first container 21 and the second container 23 in the same support structure as described above, the first container 21 and the second container 23 should be provided with different support structures. Accordingly, it is general to replace the support structure according to each type of container 20 in order to support the FOUP and the cassette. However, in the present exemplary embodiment, both the first container 21 and the second container 23 having different shapes may be supported using one support unit 200.

Hereinafter, the container storage system 100 will be described with reference to the drawings.

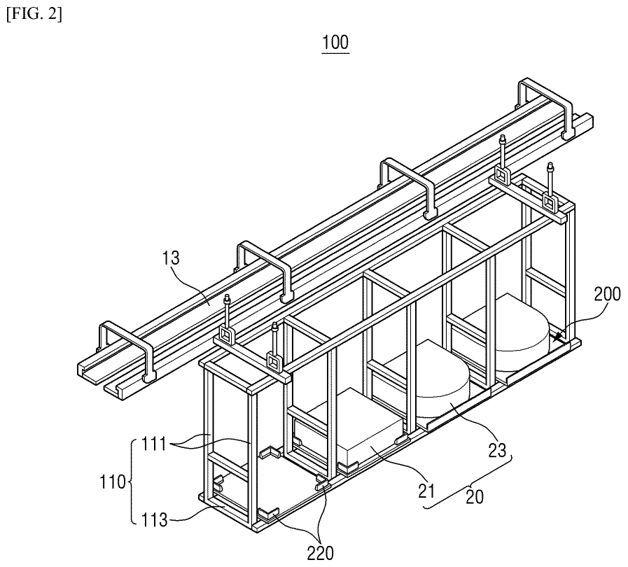

FIG. 2 is a perspective view illustrating the container storage system according to some exemplary embodiments of the present disclosure.

Referring to FIG. 2, the container storage system 100 may store the container 20 transported by a vehicle 12. The container storage system 100 may inject an inert gas in order to maintain a clean environment within the container 20, and may be provided in the form of a rack on which the container 20 may be loaded. The container storage system 100 may be installed on the ceiling, identically or similarly to the rail unit 13, and may be a side track buffer (STB) installed adjacent to a side of the rail unit 13 and storing the container 20.

However, the present is not limited thereto, and various modified examples such as a modified example in which the container storage system 100 is an under track buffer (UTB) installed in a lower region of the rail unit 13 and storing the container 20 are possible. In addition, according to a modified example of an exemplary embodiment, the container storage system 100 may be provided in a folding-type structure. That is, the container storage system 100 may be provided as various devices supporting the container 20.

For example, the container storage system 100 may include a frame 110, a support unit 200, and a guide block 150.

The frame 110 may provide a space in which the container 20 is stored. That is, the frame 110 may provide a storage space storing the container 20. The frame 110 may have an opened structure so that the container 20 may be introduced into the storage space in a lateral direction or from the top to the bottom.

When the container storage system 100 is provided as the STB, the container storage system 100 may be provided in a structure in which the container 20 may be moved to the storage space in a lateral direction of the container storage system 100 by the gripping unit and the driving module of the vehicle 12 to be carried in the storage space and the container 20 stored in the storage space may be moved from the storage space in the lateral direction to be carried out.

The frame 110 of the container storage system 100 may have a structure in which a plurality of bars are combined with each other to form a structure in which the side and the top thereof are opened. As an example, the frame 110 may be provided as a combination of a plurality of vertical bars 111 extending in a vertical direction and a horizontal bar 113 connected to the vertical bars 111 and extending in a horizontal direction. That is, in order for the container storage system 100 to form a space having a hexahedral structure, one or more vertical bars 111 and one or more horizontal bars 113 may be provided, and the frame 110 may be provided in a structure in which bars of two or more rows are combined with each other.

In the container storage system 100, the frame 110 may have a structure in which the bottom thereof is also opened by a combination of the plurality of bars, such that a structure in which the container 20 is supported so that the container 20 may be stored may be provided.

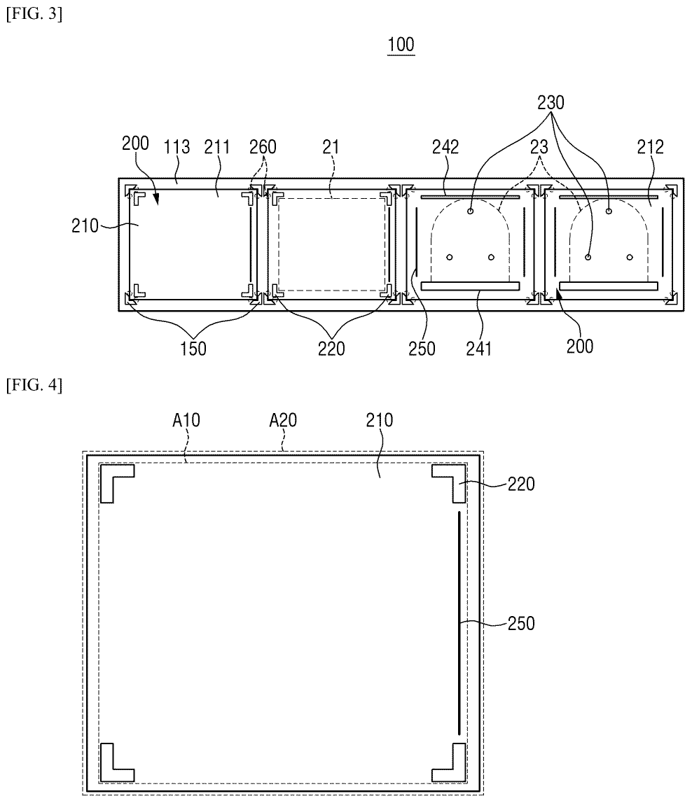

The support unit 200 may be installed in the frame 110 and may support the container 20. That is, the support unit 200 may form a bottom surface of the storage space, such that the container 20 may be stored. The support unit 200 will be described with reference to FIGS. 3 to 13.

In addition, although not illustrated in FIG. 2, the container storage system 100 may have a structure in which the support unit 200 is easily and conveniently installed according to a modified example of an exemplary embodiment. Hereinafter, a structure for easily installing the support unit 200 and a guide block 150 will be described with reference to the drawings.

FIG. 3 is a plan view illustrating the container storage system according to some exemplary embodiments of the present disclosure.

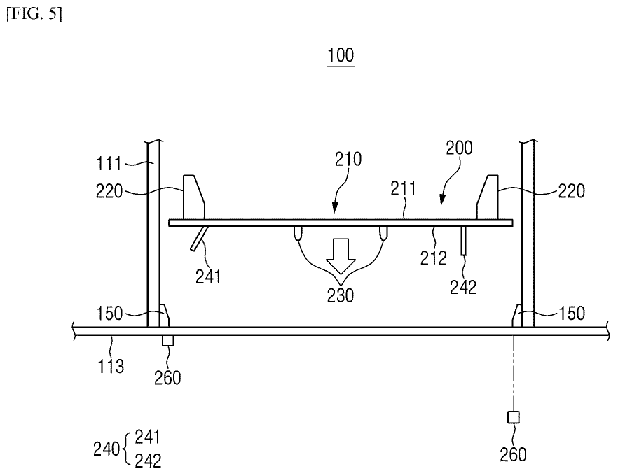

Referring to FIG. 3 (also illustrated in FIGS. 5 to 12), four guide blocks 150 of the container storage system 100 may be provided on the horizontal bar 113 of the frame 110 so as to correspond to four vertices of the support unit 200 having a rectangular shape, respectively. The guide blocks 150 may be positioned at corners of the support unit 200 in the frame 110 to surround a base 210 of the support unit 200. That is, the guide blocks 150 may surround a perimeter of the base 210 to fix a position of the base 210.

As an example, the guide block 150 may have an L shape when viewed from above so as to correspond to two or more edges of the base 210 of the support unit 200. That is, the guide block 150 may have an L shape that surrounds the edges of the base 210 and has the same angle as an angle formed at the edges of the base 210. A shape of the guide block 150 may be the same as or similar to that of a first fixing body 220 of the support unit 200.

The guide block 150 may not only fix a position of the support unit 200, but may also guide the position of the support unit 200 in a process of lowering the support unit 200. As an example, the support unit 200 may be lowered and installed from the top to the bottom. In this case, the support unit 200 may be lowered along the guide block 150.

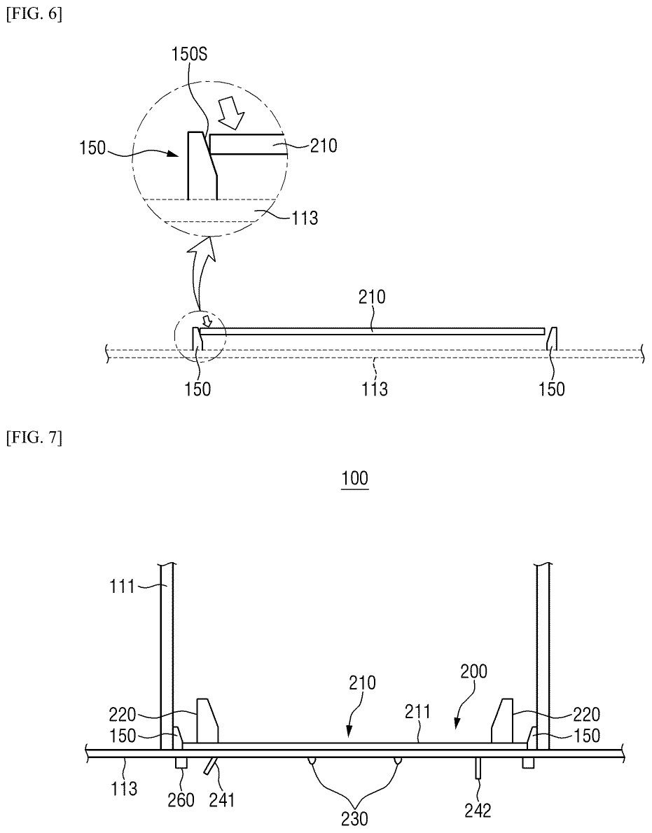

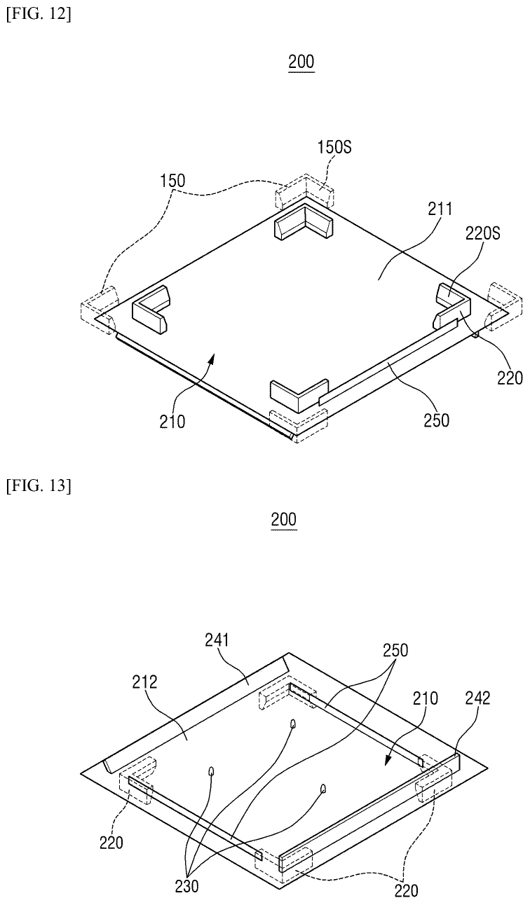

The guide block 150 may have a third inclined surface 150S formed to be inclined downward toward the base 210 so as to guide the support unit 20 (see FIGS. 6 and 12). Accordingly, the support unit 200 may be lowered in a downward direction along the third inclined surface 150S of the guide block 150 when it is installed in the frame 110. That is, the support unit 200 may be lowered while being guided by the third inclined surface 150S. Such a guide block 150 may have a greater width at a lower end thereof than at an upper end thereof.

However, the third inclined surface 150S of the guide block 150 is used to guide the support unit 200 to a correct position along the third inclined surface 150S even though the support unit 200 is not precisely disposed by an operator and is put in a range out of an error range from the correct position. Accordingly, in a process of installing the support unit 200, the support unit 200 may not be lowered while being necessarily guided by the third inclined surface 150S of the guide block 150.

In addition, the guide block 150 may extend vertically from the third inclined surface 150S in the downward direction, but this is only an example, and various modified examples are possible. In addition, the guide block 150 may be made of a material that may be resistant to friction to minimize generation of particles, such as aluminum or a Teflon resin.

Hereinafter, the support unit 200 will be described with reference to the drawings.

First, the support unit 200 will be briefly described. The support unit 200 may support the container 20 by forming a bottom surface, which is a support surface of the storage space in the container storage system 100, so that the container 20, which is the transport article, may be stored in the container storage system 100.

The support unit 200 may include the base 210, the first fixing body 220, the second fixing body 230, a separation prevention body 240, a reinforcing rib 250, and a connection module 260.

First, the base 210 will be described with reference to the drawings.

FIG. 4 is a plan view illustrating a support unit according to some exemplary embodiments of the present disclosure.

Referring FIG. 4 together with FIG. 3, the base 210 may have both surfaces provided as support surfaces on which the containers 20 are supported, and may include a first surface 211 and a second surface 212. The first surface 211 may form an upper surface or a lower surface, and the second surface 212 may form an opposite surface to the first surface 211.

For example, the first surface 211 of the base 210 may face upward so that the first container 21 is supported or the second surface 212 of the base 210 may face upward so that the second container 23 is supported. That is, the base 210 may be provided so that both surfaces thereof support the containers 20, such that when the first container 21 needs to be stored, the first surface 211 of the base 210 may be disposed to face upward, and when the second container 23 needs to be stored, the second surface 212 of the base 210 may be disposed to face upward.

That is, in the support unit 200, the first surface 211 of the base 210 faces upward or the second surface 212 of the base 210 faces upward depending on whether the first container 21 is stored or the second container 23 is stored. As illustrated in FIG. 3, by changing the first surfaces 211 and the second surfaces 212 of the bases 210 facing upward according to the numbers of first containers 21 and second containers 23 so that the first surfaces 211 of the bases 210 of some of a plurality of support units 200 in one container storage system 100 face upward and the second surfaces 212 of the bases 210 of the others of a plurality of support units 200 in one container storage system 100 face upward, it is possible to immediately cope with the numbers of first containers 21 and second containers 23.

In addition, the base 210 may be divided into regions so that the base 210 may be seated in the frame 110, regardless of whether a surface facing upward is the first surface 211 or the second surface 212. As an example, the base 210 may include a first region A10 and a second region A20.

The first region A10 is a surface on which the container 20 is supported, and may be provided with the first fixing body 220 and the second fixing body 230 and may also be provided with the separation prevention body 240 and/or the reinforcing rib 250.

The second region A20 may be a region provided outside the first region A10 and in contact with the frame 110. That is, the second region A20 may be a region where the base 210 is seated in the frame 110 without interference by the first fixing body 220, the second fixing body 230, the separation prevention body 240, and/or the reinforcing rib 250 that have structures protruding from the base 210.

In addition, the second region A20 may be a region where a position overlaps the connection module 260 in an up and down direction, such that the base 210 and the frame 110 are coupled to each other by the connection module 260. In addition, the base 210 may be made of a metal material so that the connection module 260 is attached to the base 210 by magnetic force, such that the base 210 may be easily attached to and detached from the horizontal bar 113 of the frame 110 by a magnet.

Such a base 210 is provided with the first region A10 and the second region A20, and the first fixing body 220, the second fixing body 230, the separation prevention body 240, and/or the reinforcing rib 250 do not hinder the horizontal bar 113 of the frame 110, such that the upper and lower surfaces of the base 210 may be inverted.

In addition, in the present exemplary embodiment, it has been illustrated that the base 210 is provided as a single type, such that one container 20 is supported on one base 210, but the present disclosure is not limited thereto, and various modified examples such as a modified example in which the base 210 has an area corresponding to two or more containers 20 so that two or more containers 20 are stored are possible. In this case, in order to prevent interference of the vertical bar 111 of the frame 110, a region where the vertical bar 111 is positioned between the containers 20 neighboring TO each other may be cut.

Hereinafter, the first fixing body 220, the second fixing body 230, the separation prevention body 240, the reinforcing rib 250, and the connection module 260 of the support unit 200 will be described with reference to the drawings.

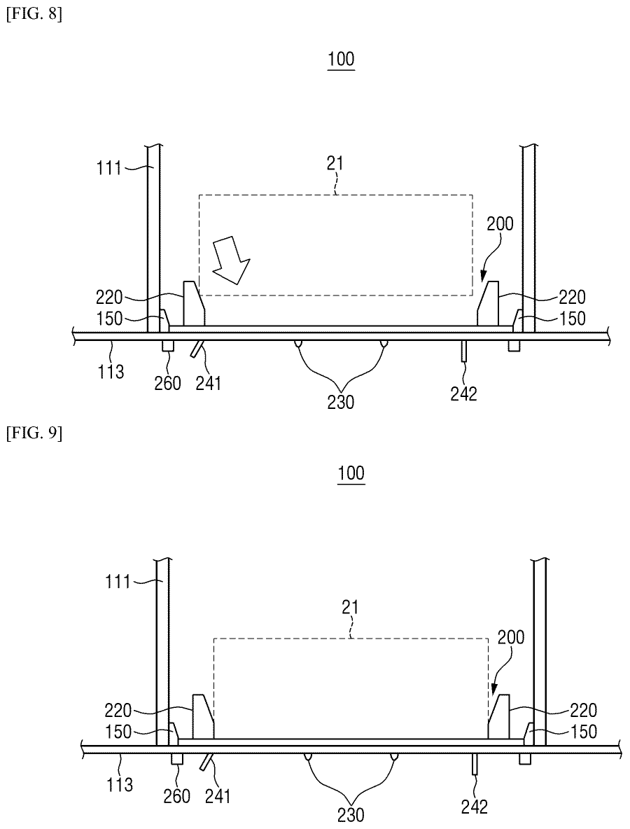

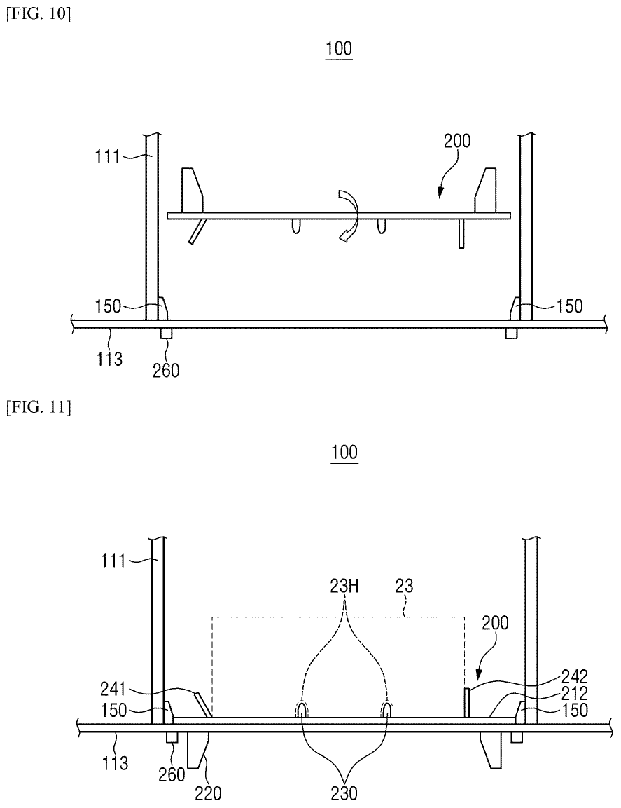

FIGS. 5 to 11 are views for describing a state in which a first container and a second container are supported. That is, FIG. 5 is a view illustrating a process in which the support unit according to some exemplary embodiments of the present disclosure is seated in the container storage system so that a first surface of the support unit faces upward, FIG. 6 is a view illustrating a form in which a base of the support unit according to some exemplary embodiments of the present disclosure is guided by a guide block, FIG. 7 is a view illustrating a state in which the support unit according to some exemplary embodiments of the present disclosure is seated in the container storage system so that the first surface of the support unit faces upward, FIG. 8 is a view illustrating a process in which a first container is seated on the first surface of the support unit according to some exemplary embodiments of the present disclosure, and FIG. 9 is a view illustrating a state in which the first container is seated on the first surface of the support unit according to some exemplary embodiments of the present disclosure. In addition, FIG. 10 is a view illustrating a process in which the support unit according to some exemplary embodiments of the present disclosure is turned over, and FIG. 11 is a view illustrating a state in which the support unit according to some exemplary embodiments of the present disclosure is seated in the container storage system so that a second surface of the support unit faces upward.

Further, FIG. 12 is a perspective view illustrating a state in which a first surface of a support unit according to a first exemplary embodiment of the present disclosure faces upward, and FIG. 13 is a perspective view illustrating a state in which a second surface of the support unit according to a first exemplary embodiment of the present disclosure faces upward.

Referring to FIGS. 5, 9, and 12 together with FIG. 4, the first surface 211 of the support unit 200 may face upward in order to store the first container 21.

Here, the first fixing body 220 and/or the reinforcing rib 250 may be formed on the first surface 211.

The first fixing body 220 may protrude from the first surface 211 and may interfere with the first container 21 to fix the first container 21. The first fixing body 220 may be made of a material that may be resistant to friction to minimize generation of particles, such as aluminum or a Teflon resin.

One or more first fixing bodies 220 may be provided along corners of the first container 21 so that edges of a lower end of the first container 21, which is the cassette, are in contact with the first fixing bodies 220. For example, the first fixing bodies 220 may be provided in the form of one or more blocks where first vertices of the first container 21 (four vertices of the lower end of the cassette) are positioned and which face or are in contact with peripheral surfaces or edges of the first container 21.

The first fixing body 220 may have an L shape when viewed from above so as to correspond to two or more edges of the first container 21. A shape of the first fixing body 220 may be similar to the shape of the guide block 150, but is not limited thereto. The first fixing body 220 may have a different size and height from the guide block 150.

The first fixing body 220 may have a first inclined surface 220S formed to be inclined downward toward the first container 21, and may have a greater width at a lower end thereof than at an upper end thereof. Such a first fixing body 220 may allow the first container 21 to be disposed at a correct position along the first inclined surface 220S even though the first container 21 is lowered out of the correct position by the first inclined surface 220S when the first container 21 is lowered.

That is, a plurality of first fixing bodies 220 may allow the first container 21 to be lowered while a lower end of the first container 21 is guided between two first inclined surfaces 220S neighboring to each other. As described above, the first container 21 may enter a space between the plurality of first fixing bodies 220.

In addition, the first fixing body 220 may extend vertically from the first inclined surface 220S in the downward direction, such that the first container 21 may be provided to be in contact with an inner side of the first fixing body 220. Since the first container 21 is in contact with a vertical surface of the first fixing body 220, the first container 21 may be stably stored even in a situation such as shaking of the frame 110. However, a gap may be formed between the first fixing body 220 and the first container 21.

An interval between the plurality of first fixing bodies 220 may be the same as the width of the first container 21 or be in the same range as the width of the first container 21 so that the first container 21 is disposed to be in contact with the plurality of first fixing bodies 220. That is, the plurality of first fixing bodies 220 may be provided at an interval for the first container 21 to be disposed and stored between the plurality of first fixing bodies 220.

Hereinafter, a process of storing the first containers 21 will be described with reference to the drawings.

First, referring to FIG. 5, the support unit 200 may be lowered from above the horizontal bar 113 of the frame 110 in the downward direction in a state in which the first surface 211 faces upward. When the support unit 200 is lowered, an operator does not need to accurately lower the support unit 200 to a correct position, and the support unit 200 may be put at the correct position by the third inclined surface 150S of the guide block 150.

That is, referring to FIG. 6, the third inclined surfaces 150S of the guide blocks 150 neighboring to and pairing with each other have a tapered structure whose width is expanded in an upward direction, such that the base 210 of the support unit 200 may be easily disposed through upper ends of the third inclined surfaces 150S of a plurality of guide blocks 150 whose entrances are expanded by the tapered structure without needing to be lowered vertically to enter the frame 110 in a state in which the base 210 of the support unit 200 is accurately disposed at the correct position. Therefore, a control time of position adjustment for putting the support unit 200 may be reduced.

Referring to FIG. 7, when the disposition of the support unit 200 is completed so that the first surface 211 faces upward on the horizontal bar 113 of the frame 110, the support unit 200 may be fixed to the horizontal bar 113 by connecting the connection module 260 to the horizontal bar 113. However, the connection module 260 is not limited to being connected to the frame 110 after the support unit 200 is disposed, and may also be in a state in which it is first attached to the frame 110.

Referring to FIGS. 8 and 9, after the support unit 200 is fixed to the frame 110, the first container 21 may be lowered onto the first surface 211 of the support unit 200. An operation of lowering the first container 21 may be performed by the vehicle 12.

A process of lowering the first container 21 onto the first surface 211 may be performed along the first inclined surfaces 220S of the first fixing bodies 220 neighboring to and pairing with each other. This is similar to a disposition process of the support unit 200 guided by the third inclined surface 150S of the guide block 150.

Here, the first inclined surfaces 220S of the first fixing bodies 220 have a tapered structure whose width is expanded in the upward direction, such that the first container 21 may be easily disposed through upper ends of the first inclined surfaces 220S of the plurality of first fixing bodies 220 whose entrances are expanded by the tapered structure without needing to be lowered vertically to enter the frame 110 in a state in which the first container 21 is accurately disposed at the correct position. Therefore, a control time of position adjustment for putting the first container 21 may be reduced.

The reinforcing rib 250 may be formed on the first surface 211 and/or the second surface 212. The reinforcing rib 250 may protrude in parallel with the edge of the base 210 between an outer side of the first container 21 and the second container 23 and a corner of the base 210.

For example, the reinforcing rib 250 is not provided in the second region A20 and is provided in the first region A10, and is disposed at a position that does not interfere with the first fixing body 220, the second fixing body 230, and the separation prevention body 240, such that the reinforcing rib 250 may not be subjected to interference of the frame 110 when the support unit 200 is disposed in the frame 110 and may not hinder the container 20 from being seated when the container 20 is seated.

The reinforcing rib 250 may be provided in a direction perpendicular to each of a first rib 241 and a second rib 242 and may reinforce strength of the base 210 so that the base 210 formed as a single plate does not twist. That is, the reinforcing rib 250 may prevent the twisting of the base 210 while preventing a thickness of the base 210 from becoming excessively great. Such a reinforcing rib 250 does not need to prevent separation of the container 20, and may thus be provided at a lower height than the first rib 241 and the second rib 242, which are the separation prevention body 240, but is not limited thereto.

Meanwhile, referring to FIG. 10, the support unit 200 may be turned over so that the first surface 211 faces downward and the second surface 212 faces upward. That is, the second surface 212 of the support unit 200 may face upward in order to store the second container 23.

Referring to FIGS. 11 and 13, the second fixing body 230, the separation prevention body 240 (the first rib 241 and the second rib 242), and/or the reinforcing rib 250 may be formed on the second surface 212.

The second fixing body 230 may protrude from the second surface 212 and may interfere with the second container 23 to fix the second container 23.

The second fixing body 230 may be provided as a guide pin inserted into the fitting hole 23H as illustrated in FIG. 11. The guide pin may be provided as, for example, a pin spring plunger, a ball spring plunger, or the like, but is not limited thereto.

In addition, the second fixing body 230 provided as the guide pin may have a length adjusted in the up and down direction, but may have a protrusion structure to hinder the first container 21 from being disposed on the second surface 212. Therefore, the second fixing body 230 is formed on the second surface 212 opposite to the first surface 211 rather than the first surface 211 on which the first container 21 is supported.

Such a second fixing body 230 may be fitted into the fitting hole 23H of the second container 23 provided as the FOUP. A plurality of second fixing bodies 230 such as three second fixing bodies 230 may protrude from the second surface 212.

In addition, when the second fixing body 230 is coupled to the base 210 by a bolt, the second fixing body 230 and the base 210 may be connected to each other by a medium whose interference is minimized, such as a flush bolt so that the bolt does not protrude to the first surface 211.

The separation prevention body 240 may protrude from the second surface 212, and may face or be in contact with a lower peripheral surface or an edge of the second container 23. For example, the separation prevention body 240 may include the first rib 241 and the second rib 242.

The first rib 241 may be positioned to correspond to one side (left side in FIG. 11) of the second container 23. That is, the first rib 241 may be positioned to face or be in contact with one side of the second container 23.

The second rib 242 may be positioned to correspond to the other side (right side in FIG. 11) of the second container 23. That is, the second rib 242 may be positioned to face or be in contact with the other side of the second container 23.

At least one of the first rib 241 and the second rib 242 may have a second inclined surface (not denoted by a reference numeral) formed to be inclined upward in an outward direction. As an example, the first rib 241 may have the second inclined surface formed to be inclined upward in the outward direction of the second container 23, and the second rib 242 may have a structure in which it stands up straight in the vertical direction.

Such a separation prevention body 240 may block both sides of the second container 23 to prevent separation/falling of the second container 23.

In addition, although not illustrated in the drawings, a reflector may be provided on the first surface and/or the second surface 212. The reflector may reflect light irradiated from a sensor (not illustrated) provided in the vehicle 12 or the frame 110. For example, when the container 20 is positioned on the support unit 200, the reflector is hidden by the container 20, such that the light irradiated from the sensor is not reflected, and thus, it may be determined that the container 20 is disposed on the support unit 200.

The connection module 260 may fix the base 210 to the frame 110 of the container storage system 100. For example, the connection module 260 may include a magnet or an electromagnet attaching the base 210 to the frame 110 of the container storage system 100 by magnetic force. However, the present disclosure is not limited thereto, and various modified examples such as a modified example in which the connection module 260 is provided as a bolt are possible.

With the container storage system 100 according to an exemplary embodiment as described above, two or more containers 20 whose shapes or types are different from each other may be supported by one support unit 200, such that there is no need to prepare and replace the support unit 200 depending on a type of the container 20. Therefore, waste of a material due to the replacement of the support unit 200 may be reduced, and the support unit 200 may be simply installed, such that operation efficiency may be improved.

The exemplary embodiments of the present disclosure have been described hereinabove with reference to the accompanying drawings, but it will be understood by one of ordinary skill in the art to which the present disclosure pertains that various modifications and alterations may be made without departing from the technical spirit or essential feature of the present disclosure. Therefore, it is to be understood that the exemplary embodiments described above are illustrative rather than being restrictive in all aspects.

What is claimed is:

1. A support unit supporting a transport article in a container storage system provided in a semiconductor fabricating plant and storing the transport article, the transport article being provided as a first container and a second container having a different shape from the first container, comprising:
a base including a first surface forming an upper surface or a lower surface and a second surface forming an opposite surface to the first surface;
a first fixing body protruding from the first surface and interfering with the first container to fix the first container; and
a second fixing body protruding from the second surface and interfering with the second container to fix the second container,
wherein the first surface of the base faces upward so that the first container is supported or the second surface of the base faces upward so that the second container is supported.

2. The support unit of claim 1, wherein the first container is provided as a cassette, and
one or more first fixing bodies are provided along corners of the first container so that edges of a lower end of the cassette are in contact with the first fixing bodies.

3. The support unit of claim 2, wherein the first fixing bodies are provided in the form of one or more blocks where first vertices of the first container are positioned and which face or are in contact with peripheral surfaces or edges of the first container.

4. The support unit of claim 3, wherein the first fixing body has a first inclined surface formed to be inclined downward toward the first container.

5. The support unit of claim 3, wherein the first fixing body has an L shape when viewed from above so as to correspond to two or more edges of the first container.

6. The support unit of claim 1, wherein the second container is provided as a front opening unified pod (FOUP) having one or more fitting holes formed at a lower end thereof, and
the second fixing body includes a guide pin inserted into the fitting hole.

7. The support unit of claim 1, further comprising a separation prevention body protruding from the second surface and facing or in contact with a lower peripheral surface or an edge of the second container.

8. The support unit of claim 7, wherein the separation prevention body includes:
a first rib positioned to correspond to one side of the second container; and
a second rib positioned to correspond to the other side of the second container.

9. The support unit of claim 8, wherein at least one of the first rib and the second rib has a second inclined surface formed to be inclined upward in an outward direction.

10. The support unit of claim 8, wherein at least one of the first surface and the second surface is provided with a reinforcing rib protruding in parallel with an edge of the base between an outer side of the first container and the second container and a corner of the base.

11. The support unit of claim 10, wherein the reinforcing rib has a lower height than the separation prevention body.

12. The support unit of claim 1, wherein the base includes:
a first region where the first fixing body and the second fixing body are provided; and
a second region provided outside the first region and seated in the container storage system.

13. The support unit of claim 12, further comprising a connection module fixing the base to the container storage system.

14. The support unit of claim 13, wherein the connection module includes a magnet or an electromagnet attaching the base to the container storage system by magnetic force.

15. A container storage system comprising:
a frame including one or more horizontal bars and one or more vertical bars connected to the horizontal bars; and
the support unit of claim 1.

16. The container storage system of claim 15, further comprising a guide block positioned at a corner of the support unit in the frame and surrounding the base of the support unit.

17. The container storage system of claim 16, wherein the guide block has a third inclined surface formed to be inclined downward toward the base.

18. The container storage system of claim 16, wherein the guide block has an L shape when viewed from above so as to correspond to two or more edges of the base.

19. A container storage system provided in a semiconductor fabricating plant and storing a transport article provided as a cassette and a FOUP having one or more fitting holes formed at a lower end thereof, comprising:
a frame including one or more horizontal bars and one or more vertical bars connected to the horizontal bars;
a support unit disposed on the horizontal bar and supporting the transport article; and
a guide block positioned at a corner of the support unit in the frame and surrounding the support unit,
wherein the support unit includes:
a base including a first surface forming an upper surface or a lower surface and a second surface forming an opposite surface to the first surface;
one or more first fixing bodies protruding from the first surface, having first inclined surfaces formed to be inclined downward toward the cassette, provided along corners of the cassette so that edges of a lower end of the cassette are in contact with the first fixing bodies, and having an L shape when viewed from above so as to correspond to two or more edges of the cassette;
a guide pin protruding from the second surface and inserted into the fitting hole so as to interfere with the FOUP to fix the FOUP;
a first rib protruding from the second surface, positioned to correspond to one side of the FOUP to face or be in contact with a lower peripheral surface or an edge of one side of the FOUP, and having a second inclined surface formed to be inclined upward in an outward direction;
a second rib protruding from the second surface and positioned to correspond to the other side of the FOUP to face or be in contact with a lower peripheral surface or an edge of the other side of the FOUP;
a reinforcing rib protrudes from at least one of the first surface and the second surface, protruding in parallel with an edge of the base between an outer side of the cassette and the FOUP and a corner of the base, and having a lower height than each of the first rib and the second rib; and
a connection module provided as an electromagnet so as to attach the base to the horizontal bar by magnetic force and fixing the base to the horizontal bar,
the guide block has a third inclined surface formed to be inclined downward toward the base,
the base includes a first region where the first fixing body, the guide pin, the first rib, the second rib, and the reinforcing rib are provided and a second region provided outside the first region and in contact with the horizontal bar, and
the first surface of the base faces upward so that the cassette is supported or the second surface of the base faces upward so that the FOUP is supported.
